(19) United States
(12) Patent Application Publication
(10) Pub. No.: US 2003/0011464 A1
(43) Pub. Date: Jan. 16, 2003

(54) Apparatus and method for a two terminal implementation of rheostat and potentiometer modes in an integrated circuit

(76) Inventors: Arthur Bruce Eck, Maricopa County, AZ (US); Craig King, Maricopa County, AZ (US)

Correspondence Address: PAUL N. KATZ, BAKER BOTTS L.L.P., ONE SHELL PLAZA, 910 LOUISIANA STREET, HOUSTON, TX, 77002-4995, US

(21) Appl. No.: 09/898,585

(22) Filed: Jul. 3, 2001

(51) Int. Cl. H01C 10/18; H03M 1/78

(52) U.S. Cl. 338/123; 341/154

(57) ABSTRACT

A digitally adjustable rheostat and/or potentiometer in a low cost integrated circuit package having a minimum number of connection pins is configurable with a memory and switch included in the integrated circuit. The switch is coupled to one or both ends of the potentiometer and configures the digitally adjustable rheostat and/or potentiometer so that a minimum number of integrated circuit package pins are required for external circuit connection to the rheostat and/or potentiometer.

### FIELD OF THE INVENTION

The present invention relates generally to integrated circuit rheostats and potentiometers, and more particularly to an apparatus and method for a two terminal implementation of a rheostat and/or a potentiometer in an integrated circuit package.

### BACKGROUND OF THE INVENTION TECHNOLOGY

Integrated circuit digital potentiometers and rheostats are replacing analog potentiometers and rheostats in electronic products because they are smaller, more easily and accurately set, are controllable remotely, and are becoming lower in cost than their analog counterparts. The difference between a rheostat and a potentiometer is that a rheostat is a two node device and a potentiometer is a three node device. Generally, the rheostat is a variable resistance between the two nodes. A first node (high end) of the potentiometer may be connected to a voltage source, a third node (low end) may be connected to ground, and a second node (wiper) may be the source of an adjustable voltage between ground and the voltage source. Connection of the potentiometer is this fashion is sometimes referred to as a voltage-scaling digital-to-analog converter (DAC).

A voltage-scaling DAC produces an analog output voltage by selectively tapping a voltage-divider resistor string connected between high and low reference voltages, with the low reference generally being set at ground. This type of converter is used most commonly as building blocks in metal oxide semiconductor (“MOS”) analog-to-digital conversion systems, where it may function as the DAC subsection of a successive-approximation-type analog-to-digital converter. For an N-bit voltage-scaling DAC, the resistor string consists of 2^{N} identical resistors connected in series, and the DAC is used as a potentiometer in which the voltage levels between the successive series-connected resistors are sampled by means of binary switches.

Replacing mechanical potentiometers and rheostats is an important and potentially very high volume application. However, a significant cost is in packaging and the number of connections (pins) required for the integrated circuit rheostat and/or potentiometer.

What is needed is an integrated circuit rheostat and/or potentiometer in a package having a minimum number of connection pins and that may also be configurable into either a digital rheostat or potentiometer.

### SUMMARY OF THE INVENTION

The invention overcomes the above-identified problems as well as other shortcomings and deficiencies of existing technologies by providing hardware and software methods, systems and apparatus for an integrated circuit digitally adjustable rheostat and/or potentiometer in a low cost package having a minimum number of connection pins. According to the present invention, at least one digitally adjustable potentiometer has three nodes, a first node connected to one end of the potentiometer, a third node connected to the other end of the potentiometer and a second node connected to an adjustable portion of the potentiometer. The second node is coupled to a pin of the integrated circuit package. The first node is coupled to another pin of the integrated circuit package and the third node may be coupled to a digitally controlled switch. The digitally controlled switch may be adapted for coupling the third node to a voltage pin or a ground pin of the integrated circuit package, or no connection (open circuit). The digitally controlled switch may be coupled to a memory, e.g., a storage register and controlled by a bit pattern in the storage register. The storage register is adapted to store serial data and control information which is received at a serial data pin of the integrated circuit package. The serial data is used to set the desired resistance value of the potentiometer and the control information may be used to configure the connection to the third node attached to the digital potentiometer of the integrated circuit. It is contemplated and within the scope of the present invention that a plurality of configurable digitally adjustable potentiometers may be fabricated in an integrated circuit die and encased in an integrated circuit package that require a minimum number of connection pins of the integrated circuit package.

In another embodiment of the invention, the first and third nodes of a digitally adjustable potentiometer are coupled to digitally controlled switches. The digitally controlled switches may be adapted for coupling the first and/or third node to a voltage pin or a ground pin of the integrated circuit package, or no connection (open circuit). The digitally controlled switches may be coupled to a memory, e.g., a storage register and controlled by a bit pattern in the storage register. The storage register is adapted to store serial data and control information which is received at a serial data pin of the integrated circuit package. The serial data is used to set the desired resistance value and the control information may be used to configure the connections to the first and/or third nodes of the digital potentiometer in the integrated circuit. It is contemplated and within the scope of the present invention that a plurality of configurable digitally adjustable potentiometers, according to this exemplary embodiment, may be fabricated in an integrated circuit die and encased in an integrated circuit package that require a minimum number of connection pins of the integrated circuit package.

The integrated circuit package may include a dual in-line package (DIP), which may comprise molded plastic dual in-line package (PDIP) or ceramic dual in-line package (CERDIP); micro lead frame (MLF); pin grid arrays (PGAs); ball grid arrays (BGAs); quad packages; thin packages, such as flat packs (FPs), thin small outline packages (TSOPs), small outline IC (SOIC) or ultrathin packages (UTPs); lead on chip (LOC) packages; chip on board (COB) packages, in which the chip is bonded directly to a printed-circuit board (PCB); and others.

In accordance with an exemplary embodiment of the present invention, an apparatus for a configurable rheostat or potentiometer in an integrated circuit package, comprising: an integrated circuit package having a plurality of external connections thereon; a digitally variable potentiometer in said integrated circuit package, said digitally variable potentiometer having first, second and third nodes, wherein the second node is coupled to a variable resistance between the first and second nodes, the first node is coupled to a first one of said plurality of external connections and the second node is coupled to a second one of said plurality of external connections; a switch in said integrated circuit package, said switch coupled between the third node of said digitally variable potentiometer and a third one of said plurality of external connections, wherein the third node is coupled to the third one of said plurality of external connections when said switch is on and the third node is not connected when said switch is off; and a memory in said integrated circuit package, said memory adapted for receiving serial data comprising a resistance value and a switch configuration, wherein the serial data comprising the resistance value is coupled from said memory to said digitally variable potentiometer for selecting a resistance thereof, and the serial data comprising the switch configuration is coupled to said switch for control thereof.

The configurable rheostat or potentiometer may further comprise another switch coupled between the first node of said digitally variable potentiometer and the first one of said plurality of external connections, wherein the first node is coupled to the first one of said plurality of external connections when said another switch is on and the first node is not connected when said switch is off. The memory is adapted to receive another switch configuration for controlling the configuration of said another switch.

In accordance with another exemplary embodiment of the present invention, an apparatus for a integrated circuit configurable rheostat or potentiometer, comprises: a digitally variable potentiometer, said digitally variable potentiometer having first, second and third nodes, wherein the second node is coupled to a variable resistance between the first and second nodes; a first switch coupled between the third node of said digitally variable potentiometer and a fourth node; and a memory for storing a resistance value and a first switch configuration, said memory being coupled to said digitally variable potentiometer and said first switch, wherein said resistance value determines the variable resistance between said first and second nodes and said first switch configuration determines whether said third node is connected or not connected to said fourth node.

The digitally variable potentiometer, first switch and memory may be in an integrated circuit package. First, second and fourth connections on said integrated circuit package may be coupled to the first, second and fourth nodes, respectively.

The integrated circuit package may be selected from the group consisting of molded plastic dual in-line package (PDIP), ceramic dual in-line package (CERDIP), micro lead frame (MLF), pin grid array (PGA), ball grid array (BGA), quad thin package (QTP), flat pack (FP), thin small outline package (TSOPs), small outline IC (SOIC), ultrathin package (UTP), lead on chip (LOC) and chip on board (COB).

A second switch may be coupled between the first node of said digitally variable potentiometer and a fifth node, wherein said memory stores a second switch configuration which determines whether said first node is connected or not connected to said fifth node. First, second and fourth connections on said integrated circuit package may be coupled to the fifth, second and fourth nodes, respectively.

A second switch may be coupled between the first node of said digitally variable potentiometer and fifth and sixth nodes, wherein said memory stores a second switch configuration which determines whether said first node is connected the fifth node or the sixth node. First, sixth, second and fourth connections on said integrated circuit package may be coupled to the fifth, sixth, second and fourth nodes, respectively. The sixth connection may be adapted for connection to a power supply voltage, V_{DD} and the fourth connection may be adapted for connection to a power supply common, V_{SS}.

The memory may be adapted for receiving serial data containing the resistance value and the first switch configuration. The serial data may be clocked into said memory with a serial clock. The memory may be a register. The memory may be non-volatile. The non-volatile memory may be electrically erasable and programmable read only memory (EEPROM). The non-volatile memory may be flash memory.

A serial data output may be coupled to a serial data input, wherein the serial data is received at the serial data input.

In accordance with still another exemplary embodiment of the present invention, an apparatus for a integrated circuit having configurable rheostats and/or potentiometers, comprises: a plurality of digitally variable potentiometers, each of said plurality of digitally variable potentiometers having first, second and third nodes, wherein the second node is coupled to a variable resistance between the first and second nodes; a plurality of first switches, each of said plurality of first switches coupled between the third node of a respective one of said plurality of digitally variable potentiometers and a respective one of a plurality of fourth nodes; and a memory for storing resistance values and configurations for each of said plurality of first switches, said memory being coupled to said plurality of digitally variable potentiometers and said plurality of first switches, wherein said resistance values determine the variable resistance between each of said first and second nodes and said configurations for each of said plurality of first switches determine whether each of said respective third nodes is connected or not connected to a respective one of said fourth nodes.

The present invention is also directed to a method of operation for configuring a rheostat or potentiometer in an integrated circuit, said method comprising the steps of: providing a digitally variable potentiometer in an integrated circuit, said digitally variable potentiometer having first, second and third nodes, wherein the second node is coupled to a variable resistance between the first and second nodes; providing a first switch coupled between the third node of said digitally variable potentiometer and a fourth node; providing a memory for storing a resistance value and a first switch configuration, said memory being coupled to said digitally variable potentiometer and said first switch, wherein said resistance value determines the variable resistance between said first and second nodes and said first switch configuration determines whether said third node is connected or not connected to said fourth node; configuring said digitally variable potentiometer as a potentiometer when said first switch connects said third node to said fourth node; and configuring said digitally variable potentiometer as a rheostat when said first switch does not connect said third node to said fourth node.

The method may further comprise the step of sending the resistance value and the first switch configuration to said memory through a serial data input.

The method may further comprise the steps of setting in said memory the resistance value to a predefined value and the first switch configuration to a predefined switch configuration.

A technical advantage of the present invention is a single potentiometer in an integrated circuit may be configured as either a potentiometer or as a rheostat and only require two external connections of an integrated circuit package.

Another technical advantage is a software control of the potentiometer or rheostat configuration.

A feature of the present invention is use of one part for circuits requiring either a potentiometer or a rheostat.

Another feature is predefined resistance and configuration values during power-up.

Another feature is a plurality of configurable potentiometers and/or rheostats in an integrated circuit.

Features and advantages of the invention will be apparent from the following description of the embodiments, given for the purpose of disclosure and taken in conjunction with the accompanying drawings.

### BRIEF DESCRIPTION OF THE DRAWINGS

A more complete understanding of the present disclosure and advantages thereof may be acquired by referring to the following description taken in conjunction with the accompanying drawing, wherein:

FIG. 1 illustrates a schematic plan view of an integrated circuit package according to an exemplary embodiment of the invention;

FIG. 2 illustrates a schematic diagram of a rheostat;

FIG. 3 illustrates a schematic diagram of a potentiometer;

FIG. 4 illustrates a schematic block diagram of a two terminal implementation of a rheostat or potentiometer in an integrated circuit package, according to an exemplary embodiment of the present invention;

FIG. 5 illustrates a schematic block diagram of a two terminal implementation of a rheostat or potentiometer in an integrated circuit package, according to another exemplary embodiment of the present invention; and

FIG. 6 illustrates a schematic block diagram of two terminal implementations of a plurality of rheostats or potentiometers in an integrated circuit package, according to yet another exemplary embodiment of the present invention.

While the present invention is susceptible to various modifications and alternative forms, specific exemplary embodiments thereof have been shown by way of example in the drawing and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF SPECIFIC EMBODIMENTS

The present invention is directed to a method, system and apparatus for a digitally adjustable rheostat and/or potentiometer in a low cost integrated circuit package having a minimum number of connection pins. A memory and switch are also included in the integrated circuit for controlling the digitally adjustable rheostat and/or potentiometer. The memory, e.g., a storage register, is adapted to receive serial data such as resistance value data and connection configuration data from a digital serial source. The resistance value data for the digitally adjustable rheostat and/or potentiometer may be stored in this memory as well as the configuration desired for the rheostat or potentiometer. The memory may be non-volatile, e.g., EEPROM or Flash memory and default settings for the rheostat or potentiometer may also be stored for use during a power-up mode. The power-up default settings may be programmed so as to protect the adjustable resistive devices in the integrated circuit and/or other integrated circuit or system components. Examples of digital potentiometers and rheostats are more fully described in commonly owned U.S. Pat. No. 6,201,491, by Brunolli, et al., issued Mar. 13, 2001, and is hereby incorporated by reference for all purposes.

Referring now to the drawing, the details of exemplary embodiments of the present invention are schematically illustrated. Like elements in the drawing will be represented by like numbers, and similar elements will be represented by like numbers with a different lower case letter suffix.

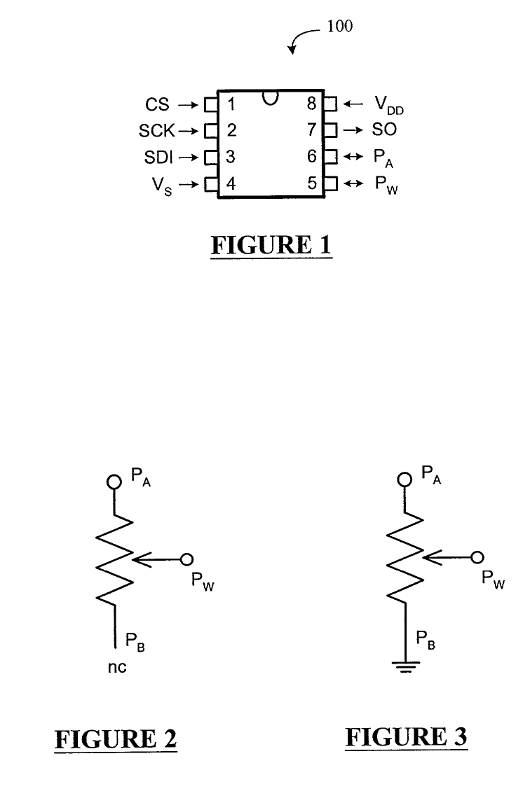

Referring to FIG. 1, depicted is a schematic plan view of an integrated circuit package according to an exemplary embodiment of the invention. The integrated circuit (IC) package, referenced by the numeral 100, and advantageously includes eight connections or pins. Each pin may be adapted and described according to the function(s) dedicated to the connection, so that all or a portion of the connections together define a functional pathway configuration at the interface between the IC potentiometer or rheostat and the system in which the IC potentiometer or rheostat may be embedded.

Examples of types of IC packages include a dual in-line package (DIP), which may comprise molded plastic dual in-line package (PDIP) or ceramic dual in-line package (CERDIP); micro lead frame (MLF); pin grid arrays (PGAs); ball grid arrays (BGAs); quad packages; thin packages, such as flat packs (FPs), thin small outline packages (TSOPs), small outline IC (SOIC) or ultrathin packages (UTPs); lead on chip (LOC) packages; chip on board (COB) packages, in which the chip is bonded directly to a printed-circuit board (PCB); and others. However, for the sake of clarity and convenience only, and without limitation as to the scope of the present invention, reference will be made herein primarily to PDIP or CERDIP ICs.

Table 1 describes an exemplary embodiment including the various functions that the IC may perform, with the functions arranged by pin dedication. Of course the exact pin and function names used in any particular embodiment or application may vary depending upon the naming convention(s) selected. Table 1 is directed to an exemplary embodiment comprising an 8-pin integrated circuit package having a digitally adjustable potentiometer or rheostat therein. The embodiment described in Table 1 in general may be suited for applications involving devices requiring variable potentiometers and/or rheostats.

TABLE 1

| PIN NAME | PIN TYPE | BUFFER TYPE | DESCRIPTION |
|---|---|---|---|
| CS | INPUT | TTL | Chip select |
| SCK | INPUT | TTL | Serial clock |
| SDI | INPUT | TTL | Serial data input |
| V_{SS} | — | P | Common or ground |
| | | | power supply |
| P_{W} | INPUT/OUTPUT | ANALOG | Potentiometer |
| | | | wiper connection |
| P_{A} | INPUT/OUTPUT | ANALOG | An end connection |
| | | | of the potentiometer |
| SO | OUTPUT | TTL | Serial data output |
| V_{DD} | — | P | Positive power |
| | | | supply |

Legend: TTL = TTL compatible input; I = input; P = power; ST = Schmitt trigger input with CMOS levels; O = output.

As depicted in FIG. 1, the IC digitally adjustable potentiometer or rheostat is in general functionally configured with the data/control inputs of serial data in (SDI), serial clock (SCK) and chip select (CS) on one side of the vertical axis along a length of the package (as opposed to across the package). The serial data output (SO) and the resistor connections P_{A} and P_{W} are on the other side of the package. A configuration including such a feature has as an advantage an increased ability to simplify routing of circuit connections for system board design and placement therein. Such advantage may prove beneficial in some cases, e.g., to an applications engineer in situations where partitioning of the printed circuit board in which the configurable IC potentiometer or rheostat is to be mounted would prove to be advantageous. Thus, as shown in the embodiment of FIG. 1, SDI, SCK and CS are on port A and SO, P_{A} and P_{W} are on port B. Further, as shown in FIG. 1, the pins of P_{A} and P_{W} advantageously are adjacent for the simplification of board layout and signal integrity.

The SDI functional pathway is adapted for coupling to a serial data and control signal of the system. Configuration connection information for the rheostat or potentiometer as well as resistance settings of the P_{W} functional pathway may be determined by information sent on the SDI functional pathway. The SCK functional pathway is adapted for coupling to a system clock. The CS functional pathway is adapted for coupling to a chip select signal line which may enable and disable configuration and resistance settings of the IC digitally adjustable rheostat or potentiometer. The SO functional pathway is adapted for sending serial data, e.g., daisy chaining additional IC digitally adjustable rheostats or potentiometers and the like. The P_{W} and P_{A} functional pathways are adapted for coupling to a system circuit requiring an adjustable resistance, current or voltage. The switch is adapted for selecting whether P_{B} is connected to V_{SS}, V_{DD} or remains unconnected. The V_{DD} and V_{SS} functional pathways are adapted for coupling to power supply voltages required for operation of the device in the system.

Referring to FIG. 2, depicted is a schematic diagram of a rheostat. A rheostat generally has two nodes, P_{A} and P_{W}, between which is an adjustable resistance. Referring to FIG. 3, depicted is a schematic diagram of a potentiometer. A potentiometer generally has three nodes, P_{A}, P_{B} and P_{W}. P_{A} is a top node, P_{B} is a bottom node and P_{W} is a node coupled to an adjustable portion of the potentiometer resistance.

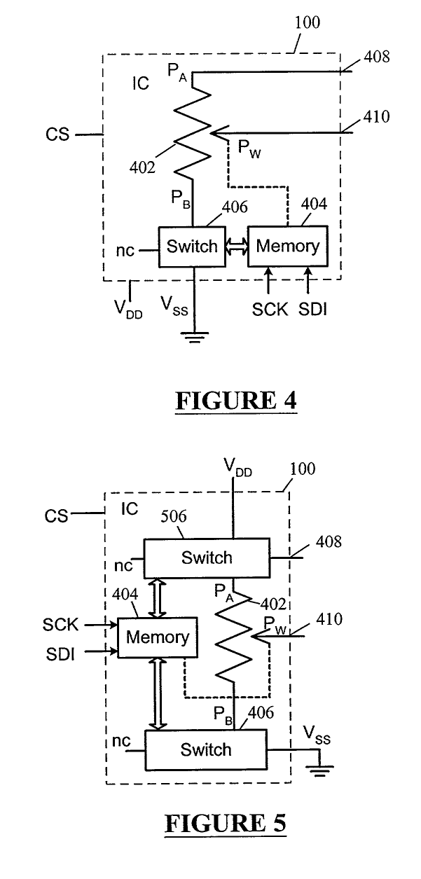

Referring to FIG. 4, depicted is a schematic block diagram of a two terminal implementation of a rheostat or potentiometer in an integrated circuit package, according to an exemplary embodiment of the present invention. An integrated circuit package 100 comprises a digitally adjustable resistor 402 having a first node P_{A}, a third node P_{B} and a second variable resistance node P_{W}; a memory 404 and a switch 406. The switch 406 is adapted to couple the third node P_{B} to either V_{SS} (ground) or no connection (nc). The switch 406 enables the resistor 402 to be configured as either a rheostat (P_{B}-nc) or a potentiometer (P_{B}-V_{SS}) while requiring only two pins 408 and 410 on the IC package 100 for external connections to the resistor 402.

The memory 404 is adapted to receive serial data on a serial data input (SDI) at a clock rate determined by a serial clock input (SCK). The memory 404 may be a random access memory (RAM), a serial input shift register and the like, and may be non-volatile memory such as EEPROM or Flash memory. Serial data is stored in the memory 404 and represents a resistance value for the variable resistor 402 and its connection configuration. The resistance value of the digitally adjustable variable resistor 402 is controlled from a bit pattern stored in the memory 404. The switch 406 is also controlled from a bit pattern stored in the memory 404.

Referring to FIG. 5, depicted is a schematic block diagram of a two terminal implementation of a rheostat or potentiometer in an integrated circuit package, according to another exemplary embodiment of the present invention. Operation of this embodiment is similar to the exemplary embodiment described in FIG. 4 with the addition of a switch 506 that is adapted to couple the first node P_{A} to either pin 408, V_{DD} or no connection (nc). The switch 506 may also be controlled by the memory 404.

It is contemplated and within the scope of the present invention that a plurality of configurable digitally adjustable potentiometers, according to the exemplary embodiments depicted in FIGS. 4 and 5, may be fabricated in an integrated circuit die and encased in an integrated circuit package that require a minimum number of connection pins of the integrated circuit package.

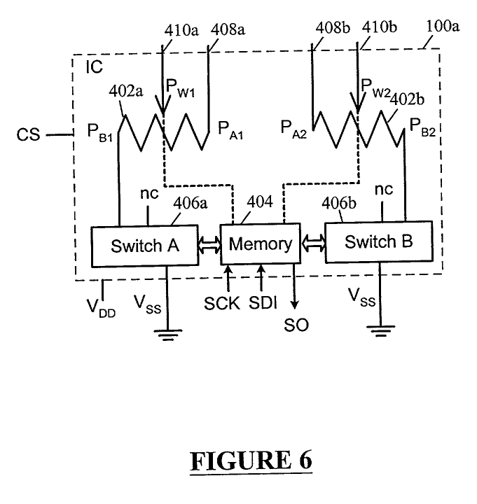

Referring to FIG. 6, depicted is a schematic block diagram of two terminal implementations of a plurality of rheostats or potentiometers in an integrated circuit package, according to yet another exemplary embodiment of the present invention. Switches 406a and 406b control the connection configurations of variable resistors 402a and 402b, respectively. Memory 404 controls the resistance values of the resistors 402a and 402b. A plurality of configurable adjustable digital resistors may be in an integrated circuit package 100a.

The invention, therefore, is well adapted to carry out the objects and attain the ends and advantages mentioned, as well as others inherent therein. While the invention has been depicted, described, and is defined by reference to exemplary embodiments of the invention, such references do not imply a limitation on the invention, and no such limitation is to be inferred. The invention is capable of considerable modification, alternation, and equivalents in form and function, as will occur to those ordinarily skilled in the pertinent arts and having the benefit of this disclosure. The depicted and described embodiments of the invention are exemplary only, and are not exhaustive of the scope of the invention. Consequently, the invention is intended to be limited only by the spirit and scope of the appended claims, giving full cognizance to equivalents in all respects.

What is claimed is:

1. A configurable rheostat or potentiometer in an integrated circuit package, comprising:
an integrated circuit package having a plurality of external connections thereon;
a digitally variable potentiometer in said integrated circuit package, said digitally variable potentiometer having first, second and third nodes, wherein the second node is coupled to a variable resistance between the first and second nodes, the first node is coupled to a first one of said plurality of external connections and the second node is coupled to a second one of said plurality of external connections;
a switch in said integrated circuit package, said switch coupled between the third node of said digitally variable potentiometer and a third one of said plurality of external connections, wherein the third node is coupled to the third one of said plurality of external connections when said switch is on and the third node is not connected when said switch is off; and
a memory in said integrated circuit package, said memory adapted for receiving serial data comprising a resistance value and a switch configuration, wherein the serial data comprising the resistance value is coupled from said memory to said digitally variable potentiometer for selecting a resistance thereof,
and the serial data comprising the switch configuration is coupled to said switch for control thereof.

2. The configurable rheostat or potentiometer according to claim 1, further comprising another switch coupled between the first node of said digitally variable potentiometer and the first one of said plurality of external connections, wherein the first node is coupled to the first one of said plurality of external connections when said another switch is on and the first node is not connected when said switch is off.

3. The configurable rheostat or potentiometer according to claim 2, wherein said memory is adapted to receive another switch configuration for controlling the configuration of said another switch.

4. An integrated circuit configurable rheostat or potentiometer, comprising:
a digitally variable potentiometer, said digitally variable potentiometer having first, second and third nodes, wherein the second node is coupled to a variable resistance between the first and second nodes;
a first switch coupled between the third node of said digitally variable potentiometer and a fourth node; and
a memory for storing a resistance value and a first switch configuration, said memory being coupled to said digitally variable potentiometer and said first switch, wherein said resistance value determines the variable resistance between said first and second nodes and said first switch configuration determines whether said third node is connected or not connected to said fourth node.

5. The integrated circuit according to claim 4, wherein said digitally variable potentiometer, said first switch and said memory are in an integrated circuit package.

6. The integrated circuit according to claim 5, further comprising first, second and fourth connections on said integrated circuit package coupled to the first, second and fourth nodes, respectively.

7. The integrated circuit according to claim 6, wherein said integrated circuit package is selected from the group consisting of molded plastic dual in-line package (PDIP), ceramic dual in-line package (CERDIP), micro lead frame (MLF), pin grid array (PGA), ball grid array (BGA), quad thin package (QTP), flat pack (FP), thin small outline package (TSOPs), small outline IC (SOIC), ultrathin package (UTP), lead on chip (LOC) and chip on board (COB).

8. The integrated circuit according to claim 5, further comprising a second switch coupled between the first node of said digitally variable potentiometer and a fifth node, wherein said memory stores a second switch configuration which determines whether said first node is connected or not connected to said fifth node.

9. The integrated circuit according to claim 8, further comprising first, second and fourth connections on said integrated circuit package coupled to the fifth, second and fourth nodes, respectively.

10. The integrated circuit according to claim 5, further comprising a second switch coupled between the first node of said digitally variable potentiometer and fifth and sixth nodes, wherein said memory stores a second switch configuration which determines whether said first node is connected the fifth node or the sixth node.

11. The integrated circuit according to claim 10, further comprising first, sixth, second and fourth connections on said integrated circuit package coupled to the fifth, sixth, second and fourth nodes, respectively.

12. The integrated circuit according to claim 11, wherein the sixth connection is adapted for connection to a power supply voltage, V_{DD} and the fourth connection is adapted for connection to a power supply common, V_{SS}.

13. The integrated circuit according to claim 4, wherein said memory is adapted for receiving serial data containing the resistance value and the first switch configuration.

14. The integrated circuit according to claim 13, wherein the serial data is clocked into said memory with a serial clock.

15. The integrated circuit according to claim 4, wherein said memory is a register.

16. The integrated circuit according to claim 4, wherein said memory is non-volatile.

17. The integrated circuit according to claim 16, wherein said non-volatile memory is electrically erasable and programmable read only memory (EEPROM).

18. The integrated circuit according to claim 16, wherein said non-volatile memory is flash memory

19. The integrated circuit according to claim 13, further comprising a serial data output coupled to a serial data input, wherein the serial data is received at the serial data input.

20. An integrated circuit having configurable rheostats and/or potentiometers, comprising:
a plurality of digitally variable potentiometers, each of said plurality of digitally variable potentiometers having first, second and third nodes, wherein the second node is coupled to a variable resistance between the first and second nodes;
a plurality of first switches, each of said plurality of first switches coupled between the third node of a respective one of said plurality of digitally variable potentiometers and a respective one of a plurality of fourth nodes; and
a memory for storing resistance values and configurations for each of said plurality of first switches, said memory being coupled to said plurality of digitally variable potentiometers and said plurality of first switches, wherein said resistance values determine the variable resistance between each of said first and second nodes and said configurations for each of said plurality of first switches determine whether each of said respective third nodes is connected or not connected to a respective one of said fourth nodes.

21. A method for configuring a rheostat or potentiometer in an integrated circuit, said method comprising the steps of:
providing a digitally variable potentiometer in an integrated circuit, said digitally variable potentiometer having first, second and third nodes, wherein the second node is coupled to a variable resistance between the first and second nodes;
providing a first switch coupled between the third node of said digitally variable potentiometer and a fourth node;
providing a memory for storing a resistance value and a first switch configuration, said memory being coupled to said digitally variable potentiometer and said first switch, wherein said resistance value determines the variable resistance between said first and second nodes and said first switch configuration determines whether said third node is connected or not connected to said fourth node;
configuring said digitally variable potentiometer as a potentiometer when said first switch connects said third node to said fourth node; and
configuring said digitally variable potentiometer as a rheostat when said first switch does not connect said third node to said fourth node.

22. The method according to claim 21, further comprising the step of sending the resistance value and the first switch configuration to said memory through a serial data input.

23. The method according to claim 21, further comprising the steps of setting in said memory the resistance value to a predefined value and the first switch configuration to a predefined switch configuration.
